(19) United States
(12) Patent Application Publication
(10) Pub. No.: US 2025/0294927 A1
(43) Pub. Date: Sep. 18, 2025

(54) NITRIDE SEMICONDUCTOR LIGHT EMITTING ELEMENT

(71) Applicant: NICHIA CORPORATION, Anan-shi (JP)

(72) Inventor: Seiichi HAYASHI, Anan-shi (JP)

(73) Assignee: NICHIA CORPORATION, Anan-shi (JP)

(21) Appl. No.: 19/034,185

(22) Filed: Jan. 22, 2025

(30) Foreign Application Priority Data
Mar. 14, 2024 (JP) 2024-040239

(51) Int. Cl. H10H 20/831; H10H 20/812; H10H 20/857

(52) U.S. Cl. CPC H10H 20/8312; H10H 20/812; H10H 20/857

(57) ABSTRACT

A nitride semiconductor light emitting element includes: a first n-type semiconductor layer containing an n-type impurity; a first p-type semiconductor layer disposed on the first n-type semiconductor layer and containing a p-type impurity; an active layer disposed on the first p-type semiconductor layer and having a hole; an intermediate layer disposed on the active layer and made of a semiconductor containing essentially no n-type impurity; a second n-type semiconductor layer disposed on the intermediate layer and containing an n-type impurity; a first electrode electrically connected to the first n-type semiconductor layer; and a second electrode electrically connected to the second n-type semiconductor layer. The intermediate layer covers at least an inner lateral surface of the hole.

### CROSS-REFERENCE TO RELATED APPLICATION

The present application claims priority to Japanese Application No. 2024-040239, filed on Mar. 14, 2024, the entire contents of which are incorporated herein by reference.

### FIELD

The present disclosure relates to a nitride semiconductor light emitting element.

### BACKGROUND

There is a need for improving the light emission efficiency of a nitride semiconductor light emitting element as its applications expand. The light emitting element disclosed in the Japanese Patent Publication No. 2020-501345 is described as one that allows for low current operation.

### SUMMARY

For such a nitride semiconductor light emitting element, there is also a need for forward voltage reduction in addition to low current operation.

One object of the present disclosure is to provide a nitride semiconductor light emitting element that allows for low current operation and forward voltage reduction.

In order to achieve the objectives described above, a nitride semiconductor light emitting element according to the present disclosure comprises: a first n-type semiconductor layer containing an n-type impurity; a first p-type semiconductor layer containing a p-type impurity disposed on the first n-type semiconductor layer; an active layer having a hole disposed on the first p-type semiconductor layer; an intermediate layer made of a semiconductor containing essentially no n-type impurity disposed on the active layer; a second n-type semiconductor layer containing an n-type impurity disposed on the intermediate layer; a first electrode electrically connected to the first n-type semiconductor layer; and a second electrode electrically connected to the second n-type semiconductor layer, the intermediate layer covering at least the inner lateral surface of the hole.

A nitride semiconductor light emitting element according to certain embodiments of the present disclosure constructed as above can achieve both low current operation and forward voltage reduction.

### BRIEF DESCRIPTION OF THE DRAWINGS

FIG. 1 is a cross-sectional view of a nitride semiconductor light emitting element according to Embodiment 1.

FIG. 2 is a cross-sectional view enlarging a portion of FIG. 1.

FIG. 3 is a cross-sectional view enlarging another portion of FIG. 1.

FIG. 4 is a cross-sectional view of a nitride semiconductor light emitting element according to Embodiment 2.

### DETAILED DESCRIPTION

Certain embodiments and examples for implementing the present disclosure will be explained below with reference to the accompanying drawings. The nitride semiconductor light emitting elements and the methods of manufacturing the same explained below are provided for the purpose of giving shape to the technical ideas of the present disclosure, and are not intended to limit the present invention to those described below unless otherwise specifically noted.

In the drawings, the same reference numerals denote members having the same functions. To make the features easily understood, the descriptions of the features are distributed among the embodiments and examples, but the constituent elements described in different embodiments and examples can be replaced or combined in part. The explanation of common features already described in embodiments appearing earlier might be omitted in the subsequent embodiments where the explanation is focused only on the differences. Similar effects attributable to similar features, in particular, might not be mentioned each time an embodiment is discussed. The sizes of and positional relationships between the members shown in each drawing might be exaggerated for clarity of explanation.

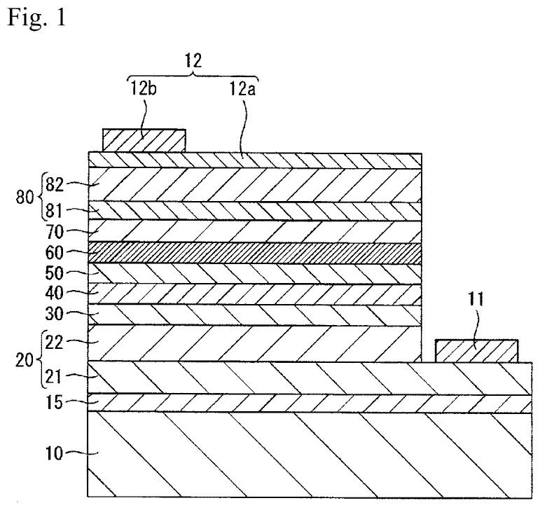

A nitride semiconductor light emitting element according to an embodiment of the present disclosure includes, as shown in FIG. 1 and others includes; a first n-type semiconductor layer 20 containing an n-type impurity; a first p-type semiconductor layer 30 containing a p-type impurity disposed on the first n-type semiconductor layer 20; an active layer 60 having a hole 65 disposed on the first p-type semiconductor layer 30; an intermediate layer 70 made of a semiconductor containing essentially no n-type impurity disposed on the active layer 60; a second n-type semiconductor layer 80 containing an n-type impurity disposed on the intermediate layer 70; a first electrode 11 electrically connected to the first n-type semiconductor layer 20; and a second electrode 12 electrically connected to the second n-type semiconductor layer 80.

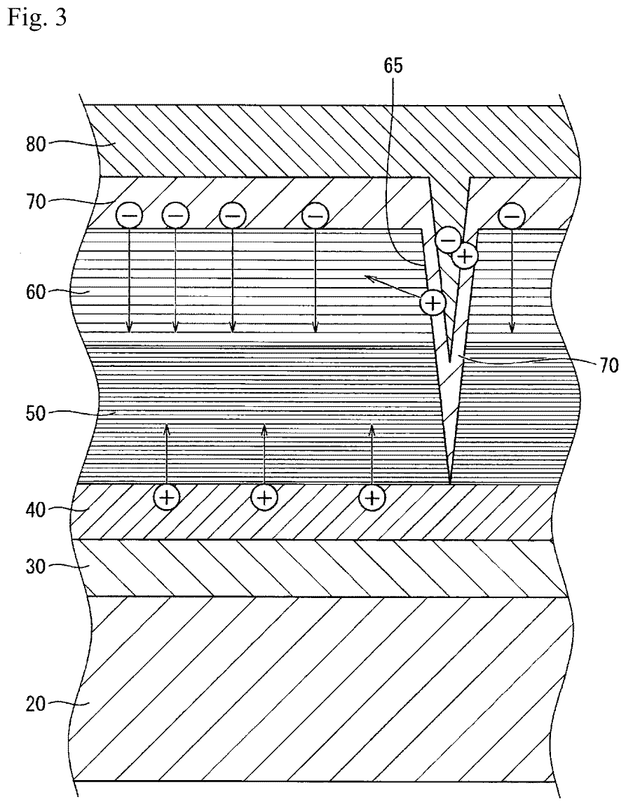

The intermediate layer 70 covers at least the inner lateral surface of the hole 65 as shown in FIG. 3.

The nitride semiconductor light emitting element constructed as above, in which the inner lateral surface of the hole 65 is covered by the intermediate layer 70 made of a semiconductor containing essentially no n-type impurity, allows for low current operation and forward voltage reduction.

In the present specification, nitride semiconductors refer to binary to quaternary semiconductors containing nitrogen (N) and at least one of aluminum (Al), gallium (Ga), and indium (In), and can include all compositions of semiconductors obtained by varying the composition ratio x and y within their ranges in the chemical formula InₓAl_{y}Ga_{1-x-y}N (0≤x≤1, 0≤y≤1, x+y≤1).

Nitride semiconductor light emitting elements of certain embodiments of the present disclosure will be described in detail below.

### Embodiment 1

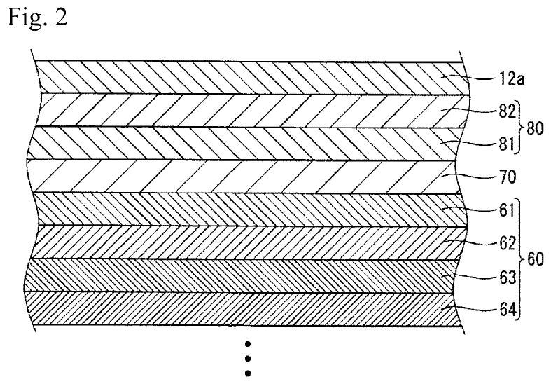

FIG. 1 is a cross-sectional view of a nitride semiconductor light emitting element according to Embodiment 1. FIG. 2 is a cross-sectional view enlarging a portion of FIG. 1, and FIG. 3 is a cross-sectional view enlarging another portion of FIG. 1.

As shown in FIG. 1, the nitride semiconductor light emitting element according to Embodiment 1 includes a substrate 10, and a first n-type semiconductor layer 20, a first p-type semiconductor layer 30, an active layer 60, an intermediate layer 70, and a second n-type semiconductor layer 80 disposed on the substrate 10.

The nitride semiconductor light emitting element according to Embodiment 1 further includes a first electrode 11 electrically connected to the first n-type semiconductor layer 20 by way of, for example, an ohmic contact with the first n-type semiconductor layer 20, and a second electrode 12 electrically connected to the second n-type semiconductor layer 80 by way of, for example, an ohmic contact with the second n-type semiconductor layer 80.

In the nitride semiconductor light emitting element according to Embodiment 1 constructed as above, the electric current from the first electrode 11 disposed on the first n-type semiconductor layer 20 is injected into the active layer 60 via the first n-type semiconductor layer 20 and the first p-type semiconductor layer 30 to allow the active layer 60 to emit light. In other words, in the nitride semiconductor light emitting element according to Embodiment 1, the first electrode 11 disposed on the first n-type semiconductor layer 20 is the positive electrode, and the second electrode 12 is the negative electrode.

The nitride semiconductor light emitting element according to Embodiment 1, as a preferred form, further includes an underlayer 15 disposed between the substrate 10 and the first n-type semiconductor layer 20, a second intermediate layer 40 and a superlattice layer 50 disposed between the first p-type semiconductor layer 30 and the active layer 60.

Moreover, the first n-type semiconductor layer 20 includes a low n-type impurity concentration n-type semiconductor layer 21 (hereinafter also referred to as a low concentration n-type semiconductor layer 21) and an n-type semiconductor layer 22 having a higher n-type impurity concentration than that of the low concentration n-type semiconductor layer 21 (hereinafter also referred to as a high concentration n-type semiconductor layer 22). The second n-type semiconductor layer 80 includes a third n-type semiconductor layer 81 and a fourth n-type semiconductor layer 82.

The nitride semiconductor light emitting element constructed as above can be manufactured by growing each of the nitride semiconductor layers on the substrate 10 while suitably changing the compositions, for example. When growing nitride semiconductor layers of the nitride semiconductor light emitting element, a hole 65 having an originating point in any of the layers located between the first n-type semiconductor layer 20 and the active layer 60 is formed so as to extend through the active layer 60. The hole here is, for example, a pit which is V shaped (conical) in a cross section.

In the nitride semiconductor light emitting element shown in FIG. 1, the hole 65 originates at a point near the border between the second intermediate layer 40 and the superlattice layer 50, and extends through the active layer 60 as shown in FIG. 3, for example. As described above, in the nitride semiconductor light emitting element shown in FIG. 1, the second electrode 12 is the negative electrode. In a nitride semiconductor light emitting element constructed in this manner, a nitride semiconductor layer having n-type conductivity is typically provided between the active layer 60 and the second electrode 12 in which the inner lateral surface of the hole is covered by the nitride semiconductor layer having n-type conductivity. The present inventors, however, learned through their diligent research and studies of forward voltage reduction that both low current operation and forward voltage reduction can be achieved when the inner lateral surface of the hole is covered by a nitride semiconductor layer containing essentially no n-type impurity.

A nitride semiconductor light emitting element according to an embodiment of the present disclosure was made based on the knowledge obtained by the present inventors mentioned above, and includes an intermediate layer 70 (hereinafter also referred to as a first intermediate layer) made of a semiconductor containing essentially no n-type impurity between the active layer 60 and the second n-type semiconductor layer 80 which covers the inner lateral surface of the hole 65.

The nitride semiconductor light emitting element constructed as above, with the first intermediate layer 70 containing essentially no n-type impurity covering the inner lateral surface of the hole 65, can be driven with low current and can reduce the forward voltage.

Such a forward voltage Vf reduction effect is thought to result because of reduction in recombination of electrons and holes that does not contribute to light emission in the hole 65 (V pit) and the vicinity. In other words, forming a layer containing an n-type impurity on the surface (inner lateral surface) of the hole 65 (V pit) and the vicinity is thought to allow for recombination of holes and electrons that does not contribute to light emission and thus for increase in the forward voltage Vf.

In contrast, the first intermediate layer 70 containing essentially no n-type impurity formed on the surface (inner lateral surface) of the hole 65 (V pit) and the vicinity is thought to reduce the recombination of holes and electrons that does not contribute to light emission. This, furthermore, is thought to facilitate the injection of holes into the active layer 60 via the first intermediate layer 70 formed on the surface (inner lateral surface) of the hole 65 (V pit) and the vicinity, as shown in FIG. 3, which can contribute to light emission and thus can lower the forward voltage Vf. The functions and the effects described above can be achieved if the first intermediate layer 70 is formed on at least a portion of the surface (inner lateral surface) of the hole 65 (V pit). Such functions and effects can be achieved even when the first intermediate layer 70 contains a p-type impurity.

In the present specification, “containing essentially no n-type impurity” refers to a concentration of under 1×10¹⁷, preferably under 1×10¹⁶. In other words, a layer “containing essentially no n-type impurity” refers to one formed by using a source gas containing no n-type impurity when the layer is grown, and may contain an n-type impurity diffused from an adjacent n-type layer.

Each layer making up a nitride semiconductor light emitting element according to Embodiment 1 will be described in detail below.

### Substrate

Materials that can be used for a substrate 10 include sapphire, Si, SiC, GaN, and the like, for example. The substrate 10 can be a growth substrate for growing a nitride semiconductor layer.

### Underlayer

An underlayer 15 is a buffer layer for reducing lattice mismatch when forming a nitride semiconductor layer on the substrate 10, and is made of, for example, a GaN layer, AlGaN layer, or AlN layer which contains essentially no n-type or p-type impurity. The underlayer 15 may comprise a buffer layer for reducing lattice mismatch during the formation of a nitride semiconductor layer on the substrate 10 and an undoped GaN layer, AlGaN layer, or AlN layer for reducing threading dislocations and pits. The thickness of the underlayer is preferably set, for example, to 0.5 μm to 8 μm, more preferably 4 μm to 6 μm.

First n-Type Semiconductor Layer 20

A first n-type semiconductor layer 20 can be made of a nitride semiconductor layer containing an n-type impurity, such as silicon (Si), germanium (Ge), or the like. In the case in which the active layer 60 is a nitride semiconductor layer containing In, for example, the nitride semiconductor layer constituting the first n-type semiconductor layer 20 is, for example, an n-type GaN layer, which may contain In and Al. In the case in which the active layer 60 is made of a nitride semiconductor layer containing Al, for example, the nitride semiconductor layer constituting the first n-type semiconductor layer 20 is, for example, an n-type AlGaN layer, which may further contain In.

Furthermore, the first n-type semiconductor layer 20 may include one or more n-type nitride semiconductor layers. In the nitride semiconductor light emitting element according to Embodiment 1, the first n-type semiconductor layer 20 includes a low concentration n-type semiconductor layer 21 and a high concentration n-type semiconductor layer 22. The high concentration n-type semiconductor layer 22 is a nitride semiconductor layer doped with a relatively high concentration n-type impurity such as Si in a range of 8×10¹⁹/cm³ to 8×10²⁰/cm³, for example, a layer that achieves a tunnel junction with the first p-type semiconductor layer 30. The high concentration n-type semiconductor layer 22 is, for example, an n-type GaN layer doped with a relatively high Si concentration of 8×10¹⁹/cm³ to 8×10²⁰/cm³ having a thickness in a range of 1 nm to 10 nm.

The low concentration n-type semiconductor layer 21 is, for example, a layer on which the first electrode 11 is formed. The concentration of an n-type impurity, Si, for example, is preferably set to 1×10¹⁸/cm⁻³ to 5×10¹⁹/cm⁻³ so as to achieve a good ohmic contact with the first electrode 11. The low concentration n-type semiconductor layer 21 can be an n-type GaN layer containing Si as an n-type impurity of 1×10¹⁸/cm⁻³ to 5×10¹⁹/cm⁻³ in concentration, for example.

Furthermore, the first n-type semiconductor layer 20 may include an undoped semiconductor layer in part. In the present specification, an undoped semiconductor layer refers to a layer not intentionally doped with an n-type impurity and a p-type impurity. The total thickness of the first n-type semiconductor layer 20 is, for example, 5 μm to 15 μm.

First p-Type Semiconductor Layer 30

A first p-type semiconductor layer 30 can be made of a nitride semiconductor layer containing a p-type impurity, such as magnesium (Mg), zinc (Zn), or the like. In the case in which the active layer 60 is a nitride semiconductor layer containing In, for example, the nitride semiconductor layer constituting the first p-type semiconductor layer 30 is, for example, a p-type GaN layer, which may contain In and Al. In the case in which the active layer 60 is made of a nitride semiconductor layer containing Al, for example, the nitride semiconductor layer constituting the first p-type semiconductor layer 30 is, for example, a p-type AlGaN layer which may further contain In.

Furthermore, the first p-type semiconductor layer 30 may include one or more p-type nitride semiconductor layers. It preferably includes as the uppermost layer, for example, as the layer achieving a tunnel junction with the high concentration n-type semiconductor layer 22, a nitride semiconductor layer doped with a relatively high concentration p-type impurity, Mg, in a range of 8×10¹⁹/cm³ to 8×10²⁰/cm³. This layer in the first p-type semiconductor layer 30 for achieving a tunnel junction is made of p-type GaN doped with Mg in a relatively high concentration of 8×10¹⁹/cm³ to 8×10²⁰/cm³ having a thickness of 10 nm to 25 nm, for example. The first p-type semiconductor layer 30 preferably includes, in addition to the layer for achieving a tunnel junction described above, a nitride semiconductor layer containing a p-type impurity, and the p-type impurity concentration of the additional nitride semiconductor layer is preferably set to 1×10¹⁸/cm⁻³ to 2×10²⁰/cm⁻³, for example, a p-type GaN layer containing Mg as a p-type impurity of 1×10¹⁸/cm⁻³ to 2×10²⁰/cm⁻³ in concentration. The first p-type semiconductor layer 30 may include an undoped semiconductor layer in part. The total thickness of the first p-type semiconductor layer 30 can be set to 0.04 μm to 0.2 μm, for example.

### Second Intermediate Layer 40

A second intermediate layer 40 can be made of a nitride semiconductor layer containing essentially no n-type impurity and p-type impurity, for example, undoped GaN. The second intermediate layer 40 has the function of reverting the deterioration of crystallinity and surface flatness attributable to the first n-type semiconductor layer 20 and the first p-type semiconductor layer 30 forming a tunnel junction, which allows a layer formed on the second intermediate layer 40 to achieve good crystallinity. The thickness of the second intermediate layer 40 can be set, for example, to 0.01 μm to 0.30 μm, for example.

### Superlattice Layer 50

A superlattice layer 50 includes first layers and second layers that are stacked alternately. For example, the lattice constant of a second layer is different from the lattice constant of a first layer. Providing a superlattice layer 50 in addition to the second intermediate layer between the first p-type semiconductor layer 30 and the active layer 60 can reduce the crystal distortion of the active layer 60 attributable to the lattice constant difference between the first p-type semiconductor layer 30 and the active layer 60. Reducing the crystal distortion of the active layer 60 can increase the internal quantum efficiency of the active layer 60. This, as a result, can increase the emission efficiency.

The compositions of the first layers and the second layers are preferably set in consideration of the composition or the band gap of the active layer 60, and when the active layer 60 has a quantum well structure, the composition or the band gap of the well layer, for example. In the case in which the well layer is made of InGaN, for example, the first layers and the second layers preferably have a lower In composition ratio than that of the well layer.

The first layers and the second layers can have different lattice constant by having a different In composition ratio, for example. At least either the first layers or the second layers are doped with a p-type impurity. Doping at least either the first layers or the second layers with a p-type impurity can reduce the forward volage Vf as described above. The p-type impurity concentration of at least either the first layers or the second layers that are doped with a p-type impurity is preferably 1×10¹⁸/cm³ to 3×10¹⁹/cm⁻³. Moreover, the p-type impurity concentration of at least either the first layers or the second layers is preferably lower than the p-type impurity concentration of the first p-type semiconductor layer 30.

For example, the In composition ratio of a first layer can be set higher than the In composition ratio of a second layer. In this case, setting the p-type impurity concentration of the first layer higher than the p-type impurity concentration of the second layer can facilitate the forward voltage Vf reduction. This is thought to be because the denser distribution of In near the upper surface of a first layer facilitates achieving low surface roughness of the upper surface of the first layer, so that crystallinity of the superlattice layer 50 is less likely to degrade even when the first layer is doped with a p-type impurity.

In the case of setting the In composition ratio of a first layer higher than the In composition ratio of a second layer and setting the p-type impurity concentration of the first layer higher than the p-type impurity concentration of a second layer, the p-type impurity concentration of the first layer is preferably set to 1×10¹⁸/cm⁻³ to 3×10¹⁹/cm⁻³. Setting the p-type impurity concentration of the first layers in this range can reduce the crystallinity degradation of the superlattice layer 50 while increasing the efficiency in supplying holes to the active layer 60. In this case, the second layers are preferably undoped layers.

In the case of setting the In composition ratio of a first layer higher than the In composition ratio of a second layer and setting the p-type impurity concentration of the first layer higher than the p-type impurity concentration of the second layer, moreover, the first layer is preferably smaller in thickness than the second layer. When the first layer, which has a relatively high p-type impurity concentration, has a smaller thickness, degradation in the crystallinity of the superlattice layer 50 can be reduced.

In the case of allowing the first n-type semiconductor layer 20 and the first p-type semiconductor layer 30 to form a tunnel junction, in particular, the impurity concentrations of the junction portions of the first n-type semiconductor layer 20 and the first p-type semiconductor layer 30 become high as described later. Providing a superlattice layer 50 can reduce the diffusion of the impurity into the active layer 60, thereby effectively inhibiting the emission efficiency reduction attributable to the diffusion of the impurity into the active layer.

In the nitride semiconductor light emitting element of Embodiment 1 including a superlattice layer 50 as constructed above, positioning the superlattice layer 50 containing a p-type impurity between the active layer 60 and the first p-type semiconductor layer 30 which contains a p-type impurity and has p-type conductivity allows for having high light intensity relative to an applied voltage while reducing the forward voltage Vf.

Furthermore, the hole 65 originating in the superlattice layer 50, in other words, having its bottom in the superlattice layer 50, extends through the active layer 60 while having a size suited for efficiently injecting holes into the active layer 60 to contribute to light emission, thereby effectively reducing the forward voltage Vf. The size of the hole 65 in the active layer 60 can be appropriately adjusted in accordance with the thickness of the superlattice layer 50. For example, the total thickness of the superlattice layer 50 is preferably set, for example, to 45 nm to 200 nm.

### Active Layer 60

An active layer 60 is a nitride semiconductor layer emitting light having a peak wavelength in a range of 200 nm to 760 nm, for example. The active layer 60 may be a multiple quantum well structure having multiple well layers and multiple barrier layers, or a single quantum well layer having a well layer and barrier layers on both sides thereof. In the case in which the active layer 60 is a single or multiple quantum well structure, the well layer(s) is/are GaN, InGaN, or AlGaN, for example, and the barrier layers are AlGaN or GaN, for example.

### Intermediate Layer 70 (First Intermediate Layer)

A first intermediate layer 70 is a layer disposed on the active layer 60 to cover at least a portion of the inner lateral surface of the hole 65.

The first intermediate layer 70 can be made of a nitride semiconductor layer that contains essentially no n-type impurity, such as silicon (Si), germanium (Ge), or the like. In the case in which the active layer 60 is made of a nitride semiconductor layer containing In, for example, the nitride semiconductor layer constituting the first intermediate layer 70 is, for example, an i-GaN layer which may contain In and Al. In the case in which the active layer 60 is made of a nitride semiconductor layer containing Al, for example, the nitride semiconductor layer constituting the first intermediate layer 70 is, for example, an i-AlGaN layer which may further include In. The first intermediate layer 70 may contain a p-type impurity.

The first intermediate layer 70 is a layer that can lower the forward voltage Vf by being formed on at least a portion of the inner lateral surface of the hole 65 (V pit) and the vicinity thereof to reduce the recombination of holes and electrons which does not contribute to light emission while allowing holes to be injected into the active layer 60 via itself to contribute to light emission.

The first intermediate layer 70 preferably covers the entire inner lateral surface of the hole 65. This can more effectively reduce the recombination of holes and electrons that does not contribute to light emission in the hole 65 and the vicinity, thereby further reducing the forward voltage Vf.

The thickness of the first intermediate layer 70 is, for example, 2 nm to 150 nm, preferably 10 nm to 120 nm, more preferably 40 nm to 80 nm. When the layer thickness is set in these ranges, the reduced distance between the active layer 60 and the n-type semiconductor layer 80 allows for efficient supply of electrons as well as the supply of holes from the hole 65 (V pit) to the active layer via the first intermediate layer 70. This can reduce the forward voltage Vf.

Second n-Type Semiconductor Layer 80

A second n-type semiconductor layer 80 includes a nitride semiconductor layer containing an n-type impurity such as silicon (Si). In the case in which the active layer 60 is made of a nitride semiconductor layer containing In, for example, the nitride semiconductor constituting the second n-type semiconductor layer 80 is, for example, an n-type GaN layer, which may contain In and Al. In the case in which the active layer 60 is made of a nitride semiconductor containing Al, for example, the nitride semiconductor constituting the second n-type semiconductor layer 80 is, for example, an n-type AlGaN layer, which may further contain In.

The thickness of the second n-type semiconductor layer 80 can be set, for example, to 100 nm to 1500 nm, preferably 200 nm to 800 nm, more preferably 300 nm to 500 nm. The impurity concentration of the second n-type semiconductor layer 80, in the case of being doped with Si as an n-type impurity, can be set to 1×10¹⁸/cm⁻³ to 5×10¹⁹/cm⁻³, for example.

The second n-type semiconductor layer 80 may include one or more n-type semiconductor layers, and may include an undoped semiconductor layer in part. The second n-type semiconductor layer 80, as shown in FIG. 1, preferably includes a third n-type semiconductor layer 81 and a fourth n-type semiconductor layer 82 on which a second electrode 12 is disposed. The third n-type semiconductor layer 81 and the fourth n-type semiconductor layer 82 may have the same composition, and for example, the third n-type semiconductor layer 81 and the fourth n-type semiconductor layer 82 may be grown to have the same composition by using different carrier gases. For example, a third n-type semiconductor layer 81 can be grown by metalorganic chemical vapor deposition (MOCVD) using nitrogen gas (N2) as a carrier gas, followed by growing a fourth n-type semiconductor layer 82 using hydrogen gas (H2) as a carrier gas so as to have the same composition as the third n-type semiconductor layer 81. When grown by metalorganic chemical vapor deposition (MOCVD) using nitrogen gas as a carrier gas, a third n-type semiconductor layer 81 can be easily formed to have a smooth surface while facilitating the filling of the hole 65, the inner lateral surface of which is covered by the first intermediate layer 70 in part or whole. By allowing a fourth n-type semiconductor layer 82 to grow on the third n-type semiconductor layer 81, which has been grown by using nitrogen gas as a carrier gas, by using hydrogen gas as a carrier gas, the fourth n-type semiconductor layer 82 grown can have a smoother surface than the third n-type semiconductor layer 81. In other words, this can achieve a lower surface roughness for the upper surface of the fourth n-type semiconductor layer 82 than the surface roughness of the upper surface of the third n-type semiconductor layer 81.

The n-type impurity concentration of the fourth n-type semiconductor layer 82 is preferably higher than the n-type impurity concentration of the third n-type semiconductor layer 81. This can reduce the contact resistance between the fourth n-type semiconductor layer 82 and the second electrode 12, thereby increasing the emission efficiency. The semiconductor layers located near the surface are easily converted into p-type due to the thermal diffusion of the Mg remaining in the chamber and Mg in the semiconductor layers. Accordingly, setting the n-type impurity concentration of the fourth n-type semiconductor layer 82 higher than the n-type impurity concentration of the third n-type semiconductor layer 81 can facilitate the conversion into an n-type to obtain the fourth n-type semiconductor layer 82, for example.

### First and Second Electrodes

A first electrode 11 and a second electrode 12 are electrically connected to the first n-type semiconductor layer 20 and the second n-type semiconductor layer 60, i.e., n-type semiconductor layers, and can be made of a metal, such as Au, Pt, Pd, Rh, Ni, W, Mo, Cr, Ti, Al, or Cu, or an alloy containing these metals. The first electrode 11 and the second electrode 12 may each be a single layer structure or a multilayer structure in which multiple layers are stacked. The first electrode 11 and the second electrode 12 can each be a multilayer structure in which a Ti layer, an Al—Si—Cu alloy layer, a Ti layer, a Pt layer, an Au layer, and a Ti layer are stacked in that order.

### Embodiment 2

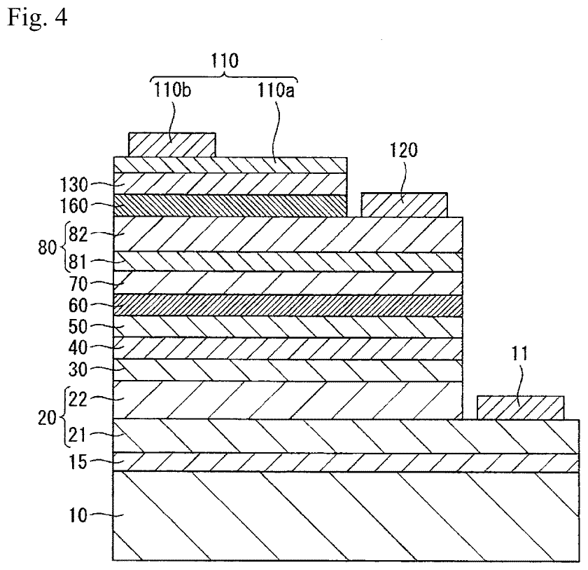

FIG. 4 is a cross-sectional view of a nitride semiconductor light emitting element according to Embodiment 2.

The nitride semiconductor light emitting element according to Embodiment 2, as shown in FIG. 4, is a nitride semiconductor light emitting element as that in Embodiment 1 and further includes a second active layer 160. The second active layer 160 is disposed on the second n-type semiconductor layer 80, and a second p-type semiconductor layer 130 is further disposed on the second active layer 160. The nitride semiconductor light emitting element according to Embodiment 2 further includes a third electrode 110 electrically connected to the second p-type semiconductor layer 130. The third electrode 110 may include an electrode layer 110a disposed in contact with the pad electrode 110b and the second p-type semiconductor layer 130. In the nitride semiconductor light emitting element according to Embodiment 2, the second electrode 120 is disposed on the second n-type semiconductor layer 80 exposed by removing the second active layer 160 and the second p-type semiconductor layer 130, for example. The first electrode 11 is disposed on the low concentration n-type semiconductor layer 21 in a similar manner to in the nitride semiconductor light emitting element according to Embodiment 1.

In the nitride semiconductor light emitting element according to Embodiment 2 constructed as above, the first electrode 11 functions as the positive electrode of the active layer 60. The third electrode 110 functions as the positive electrode of the second active layer 160. The second electrode 120 functions as the negative electrode of the active layer 60 (hereinafter also referred to as the first active layer 60) and the second active layer 160.

In the nitride semiconductor light emitting element according to Embodiment 2, applying a voltage across the first electrode 11 and the second electrode 120 allows the first active layer 60 to emit light. Applying a voltage across the third electrode 110 and the second electrode 120 allows the second active layer 160 to emit light. Consequently, the first active layer 60 and the second active layer 160 are allowed to emit light independently from each other.

Even when the first active layer 60 and the second active layer 160 are allowed to emit light simultaneously, the intensity of the light from the first active layer 60 and the second active layer 160 can be individually controlled by adjusting the voltage applied across the first electrode 11 and the second electrode 120 and the voltage applied across the third electrode 110 and the second electrode 120.

The nitride semiconductor light emitting element according to Embodiment 2 constructed as above, similar to the nitride semiconductor light emitting element according to Embodiment 1, can reduce the forward voltage Vf while increasing the light intensity relative to an applied voltage.

In the nitride semiconductor light emitting element according to Embodiment 2 constructed as above, the first active layer 60 and the second active layer 160 may emit light having the same peak wavelength or different peak wavelengths. In the nitride semiconductor light emitting element according to Embodiment 2, the second active layer 160 is positioned above the first active layer 60. Accordingly, it can achieve high color mixing quality when the peak wavelength of the light from the first active layer differs from the peak wavelength of the light from the second active layer 160. The peak wavelength of the light from the first active layer 60 can be made different from the peak wavelength of the light from the second active layer 160 by employing a different composition for the first active layer 60 from the composition of the second active layer 160. For example, the peak wavelength of the light from the first active layer 60 can be made different from the peak wavelength of the light from the second active layer 160 by setting a different In composition ratio for the first active layer 60 from the In composition ratio of the second active layer 160.

Moreover, the emission efficiency of a nitride semiconductor light emitting element might differ depending on the emission peak wavelength, for example. In the nitride semiconductor light emitting element according to Embodiment 2, as described above, even when the first active layer 60 and the second active layer 160 are lit simultaneously, the intensity of the light from the first active layer 60 and the light from the second active layer 160 can be individually controlled by adjusting the voltage applied across the first electrode 11 and the second electrode 120 and the voltage applied across the third electrode 110 and the second electrode 120. Accordingly, the nitride semiconductor light emitting element according to Embodiment 2 is allowed to emit light of different colors by adjusting the voltage applied across the first electrode 11 and the second electrode 120 and the voltage applied across the third electrode 110 and the second electrode 120 even in the case in which the peak wavelength of the light from the first active layer 60 differs from the peak wavelength of the light from the second active layer 160.

### EXAMPLES

Examples of the present disclosure will be explained below.

In the Examples described below, the nitride semiconductor light emitting elements according to Embodiment 1 shown in FIG. 1 were produced and the forward voltages Vf were measured to check the effect of including an intermediate layer 70.

Specifically, the effect of including an intermediate layer 70 was checked by comparing the forward voltage values Vf of the nitride semiconductor light emitting elements in the Examples that included an intermediate layer against that of the nitride semiconductor light emitting element in a Comparative Example that did not include an intermediate layer.

Furthermore, the film thickness dependency of the effect was evaluated by varying the thicknesses of the intermediate layer 70, the third n-type semiconductor layer 81, and the fourth n-type semiconductor layer 82 of the nitride semiconductor light emitting elements that included an intermediate layer 70 and measuring the forward voltage Vf.

Table 1 shows the compositions and the thicknesses of the semiconductor layers other than the intermediate layer 70, the third n-type semiconductor layer 81, and the fourth n-type semiconductor layer 82 of the Examples and the Comparative Example described below. Table 2 shows the compositions and the thicknesses of the intermediate layer 70, the third n-type semiconductor layer 81, and the fourth n-type semiconductor layer 82 in Examples 1 to 4.

Table 2 also shows the forward voltage values Vf measured.

TABLE 1

| Semiconductor Layer | Composition | Thickness |
|---|---|---|
| Underlayer 15 | Undoped GaN | 5 μm |
| Low Concentration | N-type GaN (n-type impurity | 5 μm |
| n-Type | concentration: | |
| Semiconductor | 1.3 × 10¹⁹/cm⁻³) | |
| Layer 21 | | |
| High Concentration | N-type GaN (n-type impurity | 5 nm |
| n-Type | concentration: | |
| Semiconductor | 4 × 10²⁰/cm⁻³) | |
| Layer 22 | | |
| First p-Type | P-type GaN (p-type impurity | 20 nm |
| Semiconductor | concentration: | |
| Layer 30 | 4 × 10²⁰/cm⁻³) | |
| Second Intermediate | Undoped GaN | 20 nm |
| Layer 40 | | |
| Superlattice | P-type InGaN/GaN | 45 nm |
| Layer 50 | superlattice | |
| First Active | InGaN/GaN multiple | 55 nm |
| Layer 60 | quantum well | |

TABLE 2

| | | | | | Comparative |
|---|---|---|---|---|---|
| | Example 1 | Example 2 | Example 3 | Example 4 | Example |
| First Intermediate | 100 Å | 200 Å | 400 Å | 800 Å | None |
| Layer 70 (N2) | | | | | |
| Undoped GaN | | | | | |
| Third n-type Semiconductor | 700 Å | 600 Å | 400 Å | None | 810 Å |
| Layer 81 (N2) | | | | | |
| N-type GaN (n-type impurity | | | | | |
| concentration: 1 × 10¹⁸/cm⁻³) | | | | | |
| Fourth n-type Semiconductor | 800 Å | 800 Å | 800 Å | 800 Å | 800 Å |
| Layer 82 (H2) | | | | | |
| N-type GaN (n-type impurity | | | | | |
| concentration: 8 × 10¹⁸/cm⁻³) | | | | | |
| Forward Voltage Vf | 6.42 V | 6.38 V | 6.31 V | 6.32 V | 6.56 V |

In Table 2, the word (N2) in the intermediate layer 70 (N2) and the third n-type semiconductor layer 81 (N2) indicates that the intermediate layer 70 and the third n-type semiconductor layer 81 were grown by using nitrogen gas (N2) as a carrier gas, and the word (H2) in the fourth n-type semiconductor layer 82 (H2) indicates that the layer was grown using hydrogen gas (H2) as a carrier gas.

As shown in Table 2, it was confirmed that the Examples 1 to 4 each including an intermediate layer 70 had a lower forward voltage Vf than the that of the Comparative Example that did not include an intermediate layer 70.

Nitride semiconductor light emitting elements according to embodiments of the present disclosure include those described below, for example.

### REFERENCE NUMERALS

10 substrate
11 first electrode
12, 120 second electrode
15 underlayer
20 first n-type semiconductor layer
21 low concentration n-type semiconductor layer
22 high concentration n-type semiconductor layer
30 first p-type semiconductor layer
40 second intermediate layer
50 superlattice layer
60 active layer, first active layer
65 hole
70 intermediate layer, first intermediate layer
80 second n-type semiconductor layer
81 third n-type semiconductor layer
82 fourth n-type semiconductor layer
110 third electrode
110a electrode layer
130 second p-type semiconductor layer
160 second active layer

What is claimed is:

1. A nitride semiconductor light emitting element comprising:
a first n-type semiconductor layer containing an n-type impurity;
a first p-type semiconductor layer disposed on the first n-type semiconductor layer and containing a p-type impurity;
an active layer disposed on the first p-type semiconductor layer and having a hole;
an intermediate layer disposed on the active layer and made of a semiconductor containing essentially no n-type impurity;
a second n-type semiconductor layer disposed on the intermediate layer and containing an n-type impurity;
a first electrode electrically connected to the first n-type semiconductor layer; and
a second electrode electrically connected to the second n-type semiconductor layer; wherein:
the intermediate layer covers at least an inner lateral surface of the hole.

2. The nitride semiconductor light emitting element according to claim 1 wherein the intermediate layer covers an entirety of the inner lateral surface of the hole.

3. The nitride semiconductor light emitting element according to claim 1 wherein the intermediate layer contains a p-type impurity.

4. The nitride semiconductor light emitting element according to claim 1 further comprising a superlattice layer disposed between the first p-type semiconductor layer and the active layer and containing a p-type impurity, wherein the hole extends through the superlattice layer.

5. The nitride semiconductor light emitting element according to claim 1 further comprising a superlattice layer disposed between the first p-type semiconductor layer and the active layer and containing a p-type impurity, wherein a bottom of the hole is positioned in the superlattice layer.

6. The nitride semiconductor light emitting element according to claim 1, wherein the second n-type semiconductor layer comprises a third n-type semiconductor layer and a fourth n-type semiconductor layer, the second electrode being disposed on the fourth n-type semiconductor layer.

7. The nitride semiconductor light emitting element according to claim 6 wherein a surface roughness of an upper surface of the fourth n-type semiconductor layer is lower than a surface roughness of an upper surface of the third n-type semiconductor layer.

8. The nitride semiconductor light emitting element according to claim 6, wherein an n-type impurity concentration of the fourth n-type semiconductor layer is higher than an n-type impurity concentration of the third n-type semiconductor layer.

9. The nitride semiconductor light emitting element according to claim 7, wherein an n-type impurity concentration of the fourth n-type semiconductor layer is higher than an n-type impurity concentration of the third n-type semiconductor layer.

10. The nitride semiconductor light emitting element according to claim 4, further comprising a second intermediate layer containing essentially no n-type impurity disposed between the first p-type semiconductor layer and the superlattice layer.

11. The nitride semiconductor light emitting element according to claim 5, further comprising a second intermediate layer containing essentially no n-type impurity disposed between the first p-type semiconductor layer and the superlattice layer.
